(19) United States
(12) Patent Application Publication
(10) Pub. No.: US 2026/0123488 A1
(43) Pub. Date: Apr. 30, 2026

(54) CIRCUIT BOARD AND SEMICONDUCTOR PACKAGE COMPRISING SAME

(71) Applicant: LG INNOTEK CO., LTD., Seoul (KR)

(72) Inventor: Won Suk JUNG, Seoul (KR)

(73) Assignee: LG INNOTEK CO., LTD., Seoul (KR)

(21) Appl. No.: 19/118,538

(22) PCT Filed: Oct. 6, 2023
(86) PCT No.: PCT/KR2023/015445

§ 371 Date: Apr. 4, 2025

(30) Foreign Application Priority Data
Oct. 6, 2022 (KR) 10-2022-0127668

(51) Int. Cl. H10W 70/68; H05K 1/11; H05K 1/185; H10W 70/63; H10W 70/652; H10W 70/685

(52) U.S. Cl. CPC H10W 70/682; H05K 1/115; H05K 1/185; H10W 70/63; H10W 70/652; H10W 70/686; H05K 2201/0275; H05K 2201/09563

(57) ABSTRACT

A circuit board according to an embodiment includes a first insulating layer; a second insulating layer disposed on the first insulating layer; a third insulating layer disposed on the second insulating layer; a fourth insulating layer embedded in the third insulating layer; and a fifth insulating layer disposed on the third insulating layer, wherein the first insulating layer, the second insulating layer, the third insulating layer, and the fourth insulating layer are provided with different materials, wherein the second insulating layer and the fifth insulating layer are provided with a same material, and a thickness in a vertical direction between an upper surface of the fourth insulating layer and an upper surface of the third insulating layer is smaller than a thickness of the second insulating layer in the vertical direction.

### TECHNICAL FIELD

An embodiment relates to a circuit board, and more particularly, to a circuit board having improved mechanical reliability and electrical reliability, and a semiconductor package including the same.

### BACKGROUND ART

As performances of electric/electronic products progresses, technologies for disposing a greater number of semiconductor devices on a semiconductor package circuit board of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

Due to these advantages, the semiconductor package as described above is widely applied to mobile devices, etc.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, or as functional parts of the semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package circuit board, thereby smoothly transmitting electrical signals between the semiconductor device and the semiconductor package circuit board having a relatively large circuit pattern compared to the circuit pattern of the semiconductor device.

An interposer may have an area greater than a total area of a plurality of semiconductor devices and/or semiconductor chiplets in order to mount a plurality of semiconductor devices and/or semiconductor chiplets as a whole, or may be disposed only in a portion for interconnection between the semiconductor devices and/or semiconductor chiplets. That is, an area of the interposer may increase as the number of semiconductor devices and/or semiconductor chiplets increases, or an area of the interposer may not increase. However, as the number of semiconductor devices and/or semiconductor chiplets increases, an area of a circuit board of the semiconductor package tends to increase. Accordingly, as the area of the semiconductor package increases, the semiconductor package has a problem of warping more significantly.

Meanwhile, a package circuit board and/or interposer applied to a semiconductor package is provided with a connection member connected to a semiconductor device and/or a semiconductor chiplet. The connection member functions to horizontally connect a plurality of semiconductor devices and/or semiconductor chiplets. Accordingly, the connection member may be embedded in the package circuit board and/or interposer. At this time, the connection member may be either an inorganic bridge or an organic bridge.

In addition, the inorganic and/or organic material constituting the connection member may include an insulating material different from an insulating layer provided in the package circuit board and/or interposer. Accordingly, coefficients of thermal expansion of the package circuit board and/or interposer and the connection member may be different from each other. As a result, when thermal stress is applied to the semiconductor package, the stress may be concentrated on the connection member embedded in the package circuit board and/or interposer. As a result, there is a problem that cracks occur in a region where the connection member is embedded in the semiconductor package.

### DISCLOSURE

### Technical Problem

The embodiment provides a circuit board having a novel structure and a semiconductor package including the same.

In addition, the embodiment provides a circuit board having improved warpage characteristics and a semiconductor package including the same.

In addition, the embodiment provides a circuit board having improved electrical reliability and mechanical reliability of a connection member and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer; a second insulating layer disposed on the first insulating layer; a third insulating layer disposed on the second insulating layer; a fourth insulating layer embedded in the third insulating layer; and a fifth insulating layer disposed on the third insulating layer, wherein the first insulating layer, the second insulating layer, the third insulating layer, and the fourth insulating layer are provided with different materials, wherein the second insulating layer and the fifth insulating layer are provided with a same material, and wherein a thickness in a vertical direction between an upper surface of the fourth insulating layer and an upper surface of the third insulating layer is smaller than a thickness of the second insulating layer in the vertical direction.

In addition, a thickness in the vertical direction between a lower surface of the fourth insulating layer and a lower surface of the third insulating layer is smaller than the thickness of the second insulating layer in the vertical direction.

In addition, the second insulating layer includes a first resin layer and a first reinforcing member provided within the first resin layer.

In addition, the fourth insulating layer includes a second resin layer and a second reinforcing member provided within the second resin layer, and a number of layers or thickness of the first reinforcing member is different from a number of layers or thickness of the second reinforcing member.

In addition, the first and second reinforcing members includes glass fibers or reinforcing fibers that are distinct from the filler.

In addition, the number of layers of the first reinforcing member is smaller than the number of layers of the second reinforcing member.

In addition, a thickness of a single layer of the first reinforcing member is smaller than a thickness of a single layer of the second reinforcing member.

In addition, the third insulating layer does not have a reinforcing member.

In addition, the circuit board further comprises a first electrode part penetrating at least some region of the second insulating layer; a second electrode part penetrating at least some region of the third insulating layer; and a third electrode part penetrating the fourth insulating layer.

In addition, the first electrode part includes a first pad part and a first through part, and the first through part has a slope whose width gradually decreases from a lower surface of the second insulating layer toward an upper surface of the second insulating layer.

In addition, the second electrode part includes a second pad part and a second through part, and the second through part has a slope whose width gradually decreases from a lower surface of the third insulating layer toward a lower surface of the fourth insulating layer, and the slope of the first through part is different from the slope of the second through part.

In addition, the third electrode part includes a third pad part and a third through part, and the third through part includes a first slope adjacent to the upper surface of the fourth insulating layer and whose width gradually decreases toward the lower surface of the fourth insulating layer; and a second slope adjacent to the lower surface of the fourth insulating layer and whose width gradually decreases toward the upper surface of the fourth insulating layer.

In addition, a thickness of the first through part in the vertical direction is greater than a thickness of the second through part in the vertical direction and smaller than a thickness of the third through part in the vertical direction, the thickness of the second through part in the vertical direction is smaller than the thickness of each of the first and third through parts in the vertical direction, and the thickness of the third through part is greater than the thickness of each of the first and second through parts in the vertical direction.

In addition, each of the first through part and the third through part has a concave portion horizontally overlapping the reinforcing member, and the second through part does not have a concave portion horizontally overlapping the reinforcing member.

In addition, a number of concave portions provided in the first through part or a thickness of a single concave portion of the first through part in the vertical direction is smaller than a number of concave portions provided in the third through part or a thickness of a single concave portion of the third through part in the vertical direction.

In addition, the fourth insulating layer has a through hole penetrating the upper surface and the lower surface of the fourth insulating layer, and the circuit board further comprises a first dummy electrode disposed on the upper surface of the fourth insulating layer adjacent to the through hole; and a second dummy electrode disposed on the lower surface of the fourth insulating layer adjacent to the through hole.

In addition, at least one of a side surface of the first dummy electrode and a side surface of the second dummy electrode is disposed on a same plane as a side wall of the through hole of the fourth insulating layer.

In addition, the side surface of the first dummy electrode, the side surface of the second dummy electrode, and the side surface of the through hole of the fourth insulating layer are disposed on a same plane.

In addition, the side surface of the first dummy electrode and the side surface of the second dummy electrode are misaligned from each other along the vertical direction.

In addition, an upper width and a lower width of the through hole are different from each other.

In addition, the semiconductor package comprises a connection member disposed in the through hole.

In addition, the connection member is any one of a semiconductor active device, a semiconductor passive device, an inorganic bridge, and an organic bridge.

In addition, an upper surface of the first dummy electrode has a step difference from an upper surface of a terminal of the connection member.

In addition, the upper surface of the terminal of the connection member is positioned higher than the upper surface of the first dummy electrode, and a vertical distance of the step difference is 8 μm or less.

### Advantageous Effects

The semiconductor package of the embodiment includes a first insulating layer, a second insulating layer disposed on the first insulating layer, a third insulating layer disposed on the second insulating layer, a fourth insulating layer embedded in the third insulating layer, and a fifth insulating layer disposed on the third insulating layer, wherein the first insulating layer, the second insulating layer, the third insulating layer, and the fourth insulating layer are formed of different materials, the second insulating layer and the fifth insulating layer are formed of a same material, and a thickness in a vertical direction between an upper surface of the fourth insulating layer and an upper surface of the third insulating layer may be smaller than a thickness of the second insulating layer in a vertical direction. Through this, the embodiment can reduce a thickness of the semiconductor package while preventing the semiconductor package from being bent in a specific direction by using the third insulating layer.

Specifically, the third insulating layer may have a relatively low Young's modulus, thereby suppressing an occurrence of warpage acting on the semiconductor package, and further preventing the semiconductor package from being greatly bent in a specific direction while absorbing an impact applied to the semiconductor package. Through this, the embodiment may solve a problem of deterioration of operating characteristics due to the semiconductor package being greatly bent in a specific direction, and further may solve a problem of damage to the connection member disposed in the third insulating layer due to the impact. In addition, the embodiment may arrange an electrode part connected to the connection member using the third insulating layer, thereby improving an alignment between the electrode part and the connection member.

In addition, the fourth insulating layer may include a through hole, and the connection member may be disposed in the through hole. In addition, a first dummy electrode may be provided at an upper surface of the fourth insulating layer, and a second dummy electrode may be provided at a lower surface of the fourth insulating layer. At least one side surface of the first dummy electrode and the second dummy electrode may be located on a same plane as a sidewall of the through hole. The first and second dummy electrodes may be electrodes used to form the through hole by a laser process. In addition, the embodiment may use the first and second dummy electrodes to make upper and lower widths of the through hole substantially the same, thereby reducing an area of a dead region that increases by a difference between the upper and lower widths. Accordingly, the embodiment can reduce a thickness of the semiconductor package.

In addition, the embodiment may change a shape of the through hole by making the first dummy electrode and the second dummy electrode misaligned along the vertical direction. Through this, the embodiment may freely change a shape of the through hole according to a shape of the connection member, thereby improving a degree of design freedom.

In addition, the embodiment may have a step between an upper surface of a terminal of the connection member and an upper surface of the first dummy electrode, and manage the step to be maintained below a certain level. Through this, the embodiment may increase a connection alignment between the electrode part and the terminal, and further minimize voids that occur in a process of filling the through hole with an insulating material.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 1f is a cross-sectional view showing a semiconductor package according to a sixth embodiment.

FIG. 1g is a cross-sectional view showing a semiconductor package according to a seventh embodiment.

FIG. 2 is a cross-sectional view showing a circuit board according to a first embodiment.

FIG. 3 is a cross-sectional view showing a first electrode part of FIG. 2.

FIG. 4 is a cross-sectional view showing a second electrode part of FIG. 2.

FIG. 5 is a cross-sectional view showing a third electrode part of FIG. 2.

FIG. 6 is a plan view showing a dummy electrode of a third electrode part according to an embodiment.

FIG. 7 is a cross-sectional view showing a dummy electrode and a through hole according to a first embodiment.

FIG. 8 is a cross-sectional view showing a dummy electrode and a through hole according to a second embodiment.

FIG. 9 is a cross-sectional view showing a dummy electrode and a through hole according to a third embodiment.

FIG. 10 is a cross-sectional view showing positions of terminals of a dummy electrode and a connection member according to a first embodiment.

FIG. 11 is a cross-sectional view showing positions of terminals of a dummy electrode and a connection member according to a second embodiment.

FIG. 12 is a cross-sectional view showing a circuit board according to a second embodiment.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention. Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, the circuit board in one embodiment may be a first circuit board described below.

In addition, the circuit board in another embodiment may be a second circuit board described below.

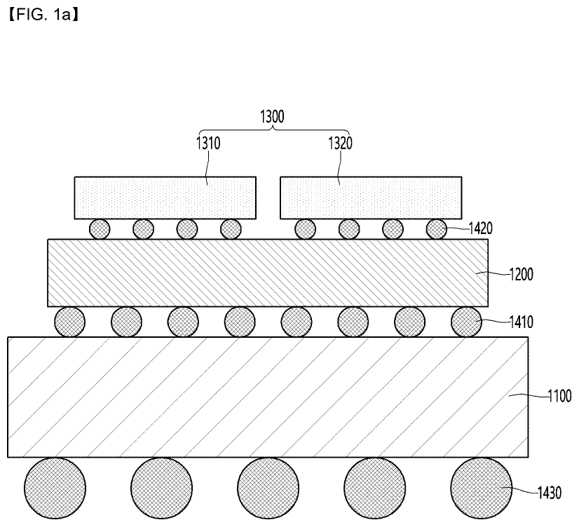

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, FIG. 1e is a cross-sectional view showing a semiconductor package according to a fifth embodiment, FIG. 1f is a cross-sectional view showing a semiconductor package according to a sixth embodiment, and FIG. 1g is a cross-sectional view showing a semiconductor package according to a seventh embodiment.

Referring to FIG. 1a, the semiconductor package according to the first embodiment may include a first circuit board 1100, a second circuit board 1200, and a semiconductor device 1300.

The first circuit board 1100 may mean a package substrate.

For example, the first circuit board 1100 may provide a space to which at least one external circuit board is coupled. The external circuit board may refer to a second circuit board 1200 coupled to the first circuit board 1100. Also, the external circuit board may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 may include at least one insulating layer, an electrode part disposed on the at least one insulating layer.

A second circuit board 1200 may be disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package substrate.

FIG. 1a illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one semiconductor device 1300 and the first circuit board 1100.

In an embodiment, the second circuit board 1200 may be an active interposer that functions as a semiconductor device. When the second circuit board 1200 functions as a semiconductor device, the semiconductor package of the embodiment may have a structure that is vertically stacked on the first circuit board 1100 and may have functions of multiple logic chips. Having the function of a logic chip may mean that it may have functions of an active device and a passive device. In a case of an active device, characteristics of current and voltage may not be linear unlike a passive device, and in a case of an active interposer, it may have the function of an active device. In addition, the active interposer may perform a function of a corresponding logic chip while performing a signal transmission function between a second logic chip disposed thereon and the first circuit board 1100.

According to another embodiment, the second circuit board 1200 may be a passive interposer. For example, the second circuit board 1200 may function as a signal relay between the semiconductor device 1300 and the first circuit board 1100, and can have a passive device function such as a resistor, capacitor, or inductor. For example, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

The semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment may include a connection part.

For example, the semiconductor package may include a first connection part 1410 disposed between the first circuit board 1100 and the second circuit board 1200. The first connection part 1410 may electrically connect the second circuit board 1200 to the first circuit board 1100 while coupling them.

For example, the semiconductor package may include the second connection part 1420 disposed between the second circuit board 1200 and the semiconductor device 1300. The second connection part 1420 may electrically connect the semiconductor device 1300 to the second circuit board 1200 while coupling them.

The semiconductor package may include a third connection part 1430 disposed on a lower surface of the first circuit board 1100. The third connection part 1430 may electrically connect the first circuit board 1100 to the main board while coupling them.

At this time, the first connection part 1410, the second connection part 1420, and the third connection part 1430 may electrically connect between the plurality of components by using at least one bonding method of wire bonding, solder bonding and metal-to-metal direct bonding. That is, since the first connection part 1410, the second connection part 1420, and the third connection part 1430 have a function of electrically connecting a plurality of components, when the metal-to-metal direct bonding is used, the connection part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second connection part 1420. In this case, the second connection part 1420 may mean a metal layer formed between a plurality of components by the recrystallization.

Specifically, the first connection part 1410, the second connection part 1420, and the third connection part 1430 may couple a plurality of components to each other by a thermal compression (TC) bonding method. The thermal compression bonding may refer to a method of directly coupling a plurality of components by applying heat and pressure to the first connection part 1410, the second connection part 1420, and the third connection part 1430.

At this time, at least one of the first circuit board 1100 and the second circuit board 1200 may be provided with a protrusion that protrudes outwardly away from the insulating layer of the corresponding board, on which the first connection part 1410, the second connection part 1420, and the third connection part 1430 are disposed. The protrusion may protrude outwardly from the first circuit board 1100 or the second circuit board 1200.

The protrusion may be referred to as a bump. The protrusion may also be referred to as a post. The protrusion may also be referred to as a pillar. Preferably, the protrusion may refer to an electrode on which a second connection part 1420 for coupling with the semiconductor device 1300 is disposed among the electrodes of the second circuit board 1200. That is, as the pitch of the terminals of the semiconductor device 1300 becomes finer, a short circuit may occur between the plurality of second connection parts 1420 that are respectively connected to the plurality of terminals of the semiconductor device 1300 by a conductive adhesive such as a solder. Therefore, in the embodiment, thermal compression bonding may be performed to reduce a volume of the second connection part 1420. In addition, in order to secure diffusion prevention and alignment to prevent an intermetallic compound (IMC) formed between a conductive adhesive such as solder and a protrusion from diffusing into the interposer and/or the circuit board, a protrusion may be included in the electrode of the second circuit board 1200 on which the second connection part 1420 is disposed.

Meanwhile, referring to FIG. 1b, the semiconductor package of the second embodiment may differ from the semiconductor package of the first embodiment in that the connection member 1210 is disposed on the second circuit board 1200. The connection member 1210 may be referred to as a bridge circuit board. For example, the connection member 1210 may include a redistribution layer. The connection member 1210 may perform a function of electrically connecting a plurality of semiconductor devices horizontally to each other. For example, since the area that a semiconductor device should generally have been too large, the connection member 1210 may include a redistribution layer. Since the semiconductor package and the semiconductor device have a large difference in a width or spacing of the circuit pattern, etc., a buffering role of the circuit pattern for electrical connection is required. The buffering role may mean having a size between a width or spacing of the circuit pattern of the semiconductor package and a width or spacing of the circuit pattern of the semiconductor device, and the redistribution layer may include a function of performing the buffering role.

In an embodiment, the connection member 1210 may be an inorganic bridge. For example, the inorganic bridge may be a silicon bridge. That is, the connection member 1210 may include a silicon circuit board and a redistribution layer disposed on the silicon circuit board.

In another embodiment, the connection member 1210 may be an organic bridge. For example, the connection member 1210 may include an organic material. For example, the connection member 1210 may include an organic circuit board including an organic material instead of the silicon circuit board.

The connection member 1210 may be embedded in the second circuit board 1200, but is not limited thereto. For example, the connection member 1210 may be disposed on the second circuit board 1200 to have a protruding structure.

Also, the second circuit board 1200 may include a cavity, and the connection member 1210 may be disposed in the cavity of the second circuit board 1200.

The connection member 1210 may horizontally connect a plurality of semiconductor devices disposed on the second circuit board 1200.

Referring to FIG. 1c, the semiconductor package according to the third embodiment may include a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a package substrate while performing an interposer function.

The first connection part 1410 disposed on the lower surface of the second circuit board 1200 may couple the second circuit board 1200 to the main board of the electronic device.

Referring to FIG. 1d, the semiconductor package according to the fourth embodiment may include a first circuit board 1100 and a semiconductor device 1300.

In this case, the semiconductor package of the fourth embodiment may have a structure in which the second circuit board 1200 is omitted compared to the semiconductor package of the second embodiment.

That is, the first circuit board 1100 of the fourth embodiment can function as a package circuit board while also performing the function of connecting the semiconductor device 1300 and a main board. To this end, the first circuit board 1100 may include a connection member 1110 for connecting the plurality of semiconductor devices. The connection member 1110 may be an inorganic bridge or an organic material bridge connecting a plurality of semiconductor devices.

Referring to FIG. 1e, the semiconductor package of the fifth embodiment further may include a third semiconductor device 1330 compared to the semiconductor package of the fourth embodiment.

To this end, a fourth connection part 1440 may be disposed on the lower surface of the first circuit board 1100.

In addition, a third semiconductor device 1330 may be disposed on the fourth connection part 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 1c.

Referring to FIG. 1f, the semiconductor package according to the sixth embodiment may include a first circuit board 1100. A first semiconductor device 1310 may be disposed on the first circuit board 1100. To this end, a first connection part 1410 may be disposed between the first circuit board 1100 and the first semiconductor device 1310.

In addition, the first circuit board 1100 may include a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A second semiconductor device 1320 may be disposed on the conductive coupling portion 1450. In this case, the second semiconductor device 1320 may be connected to the first circuit board 1100 through the conductive coupling portion 1450. In addition, a second connection part 1420 may be disposed on the first semiconductor device 1310 and the second semiconductor device 1320.

Accordingly, the second semiconductor device 1320 may be electrically connected to the first semiconductor device 1310 through the second connection part 1420.

That is, the second semiconductor device 1320 may be connected to the first circuit board 1100 through the conductive coupling portion 1450, and may be also connected to the first semiconductor device 1310 through the second connection part 1420.

In this case, the second semiconductor device 1320 may receive a power signal and/or electric power through the conductive coupling portion 1450. Also, the second semiconductor device 1320 may transmit and receive a communication signal to and from the first semiconductor device 1310 through the second connection part 1420.

The semiconductor package according to the sixth embodiment may provide a power signal and/or electric power to the second semiconductor device 1320 through the conductive coupling portion 1450, thereby providing sufficient power for driving the second semiconductor device 1320 or enabling smooth control of a power operation.

Accordingly, the embodiment may improve the driving characteristics of the second semiconductor device 1320. That is, the embodiment may solve a problem of insufficient power provided to the second semiconductor device 1320. Furthermore, in the embodiment, at least one of a power signal, an electric power, and a communication signal of the second semiconductor device 1320 may be provided through different paths through the conductive coupling portion 1450 and the second connection part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of package circuit boards are stacked and may be disposed on the first circuit board 1100. For example, the second semiconductor device 1320 may be a memory package including a memory chip. In addition, the memory package may be coupled on the conductive coupling portion 1450. In this case, the memory package may not be connected to the first semiconductor device 1310.

Meanwhile, the semiconductor package in the sixth embodiment may include a molding member 1460. The molding member 1460 may be disposed between the first circuit board 1100 and the second semiconductor device 1320. For example, the molding member 1460 may mold the first connecting member 1410, the second connecting member 1420, the first semiconductor device 1310, and the conductive coupling portion 1450.

Referring to FIG. 1g, the semiconductor package according to the seventh embodiment may include a first circuit board 1100, a first connection part 1410, a first connection part 1410, a semiconductor device 1300, and a third connection part 1430.

In this case, the semiconductor package of the seventh embodiment may differ from the semiconductor package of the fourth embodiment in that the first circuit board 1100 includes a plurality of circuit board layers while the connection member 1110 is omitted.

The first circuit board 1100 may include a plurality of circuit board layers. For example, the first circuit board 1100 may include a first circuit board layer 1100A corresponding to a package substrate and a second circuit board layer 1100B corresponding to the connection member.

In other words, the semiconductor package of the seventh embodiment may include a first circuit board layer 1100A and a second circuit board layer 1100B in which the first circuit board (package circuit board, 1100) and the second circuit board (interposer, 1200) disclosed in FIG. 1a are integrally formed. A material of the insulating layer of the second circuit board layer 1100B may be different from a material of an insulating layer of the first circuit board layer 1100A. For example, the material of an insulating layer of the second circuit board layer 1100B may include a photocurable material. For example, the second circuit board layer 1100B may be a photo imageable dielectric (PID). In addition, since the second circuit board layer 1100B includes a photocurable material, it is possible to miniaturize the electrode. Accordingly, in the seventh embodiment, the second circuit board layer 1100B may be formed by sequentially stacking an insulating layer of a photo-curable material on the first circuit board layer 1100A and forming a miniaturized electrode on the insulating layer of the photo-curable material. Accordingly, the second circuit board layer 1100B may include a redistribution layer function including a micro-electrode and may include a function of horizontally connecting a plurality of semiconductor devices 1310 and 1320.

Before describing the circuit board of the embodiment, the circuit board described below may mean any one of the circuit boards included in the previous semiconductor package. For example, the circuit board described below may mean any one of the first circuit board 1100 and the second circuit board 1200 included in the semiconductor package of the first to seventh embodiments.

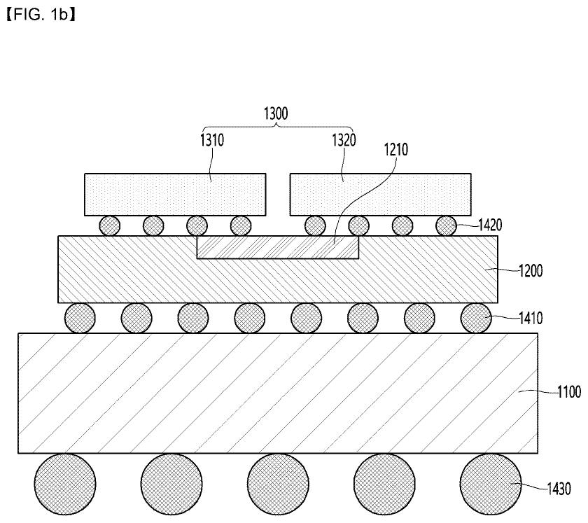

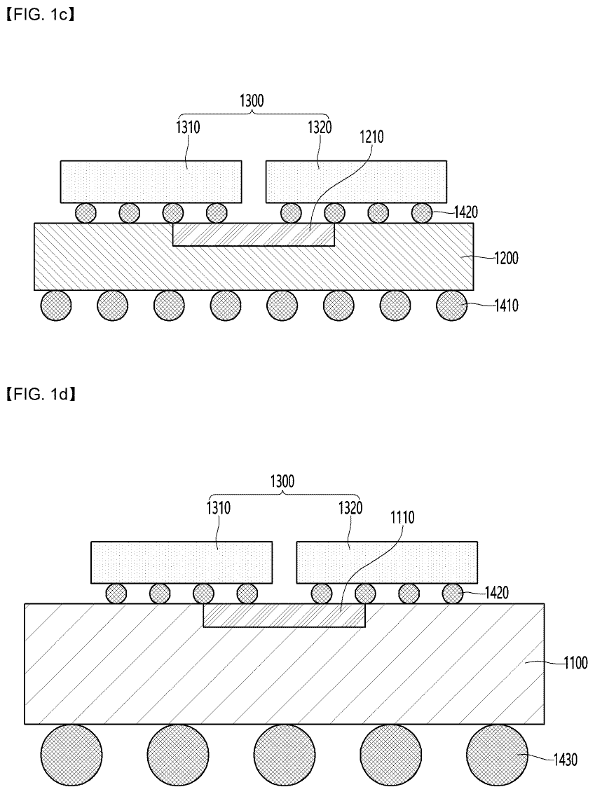

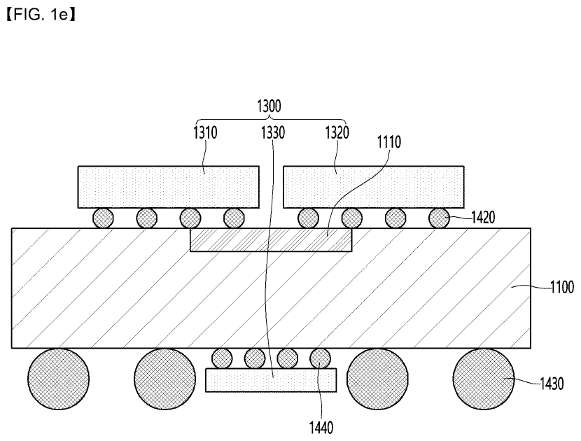

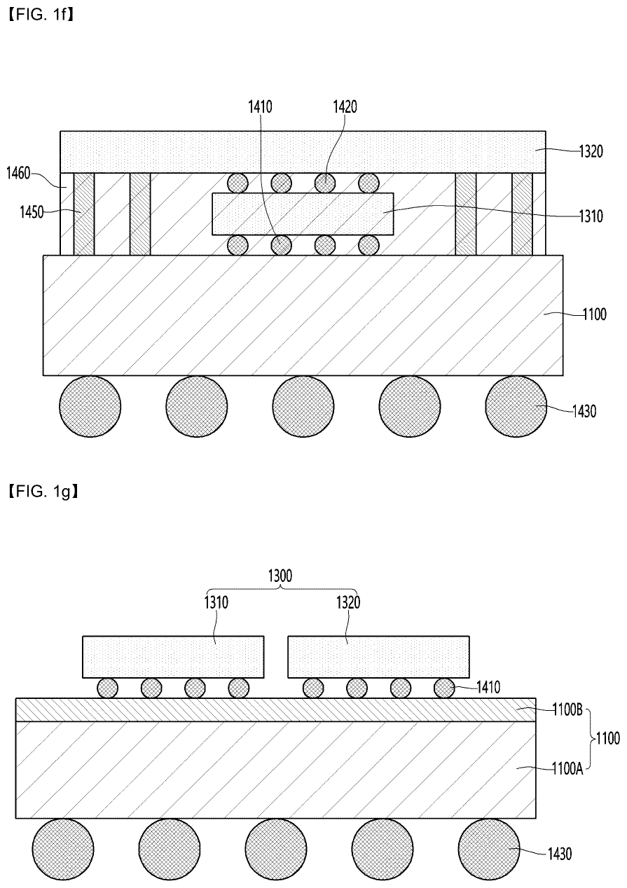

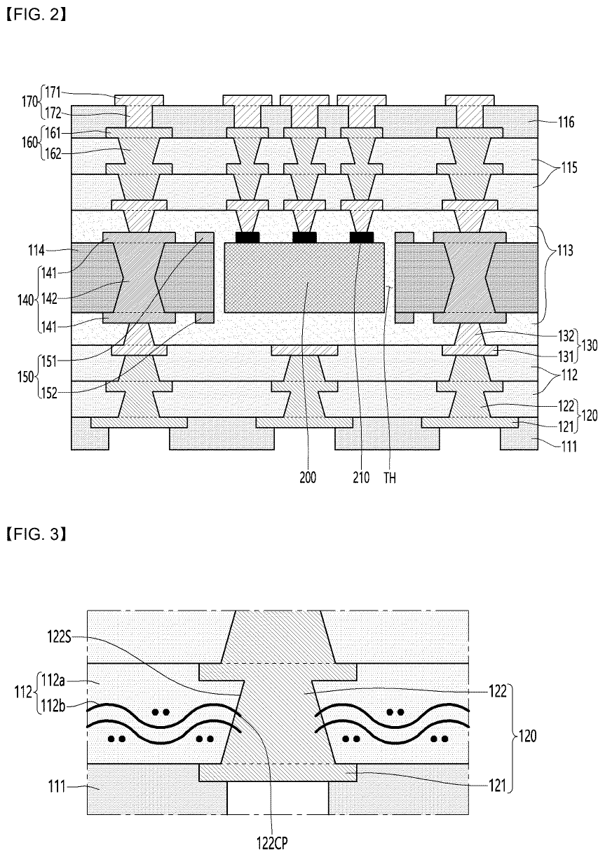

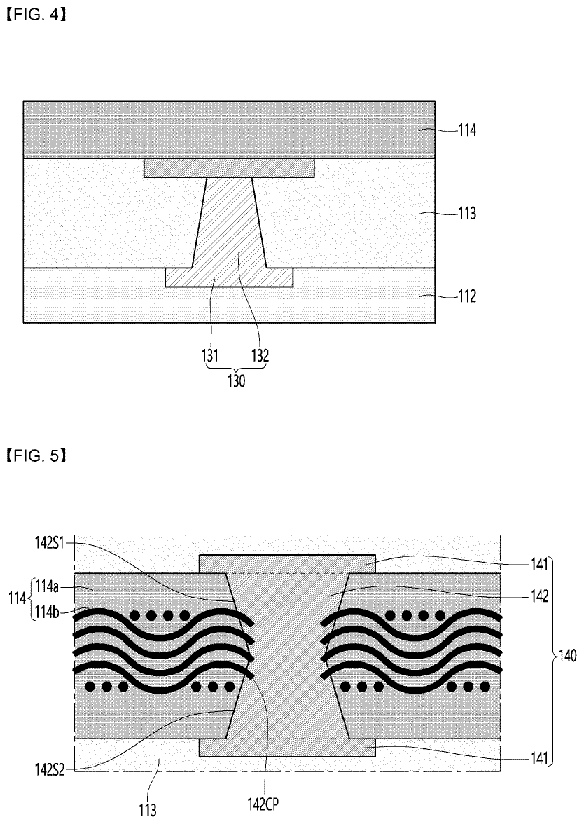

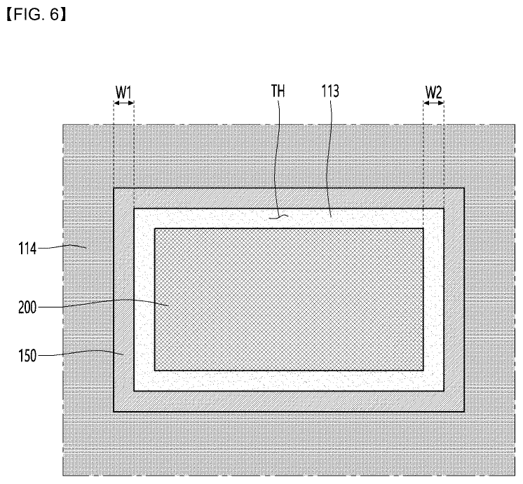

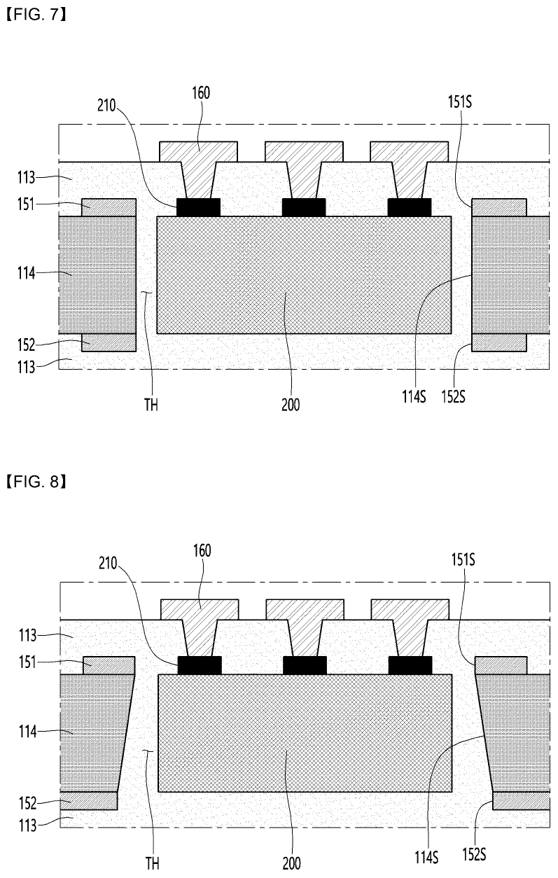

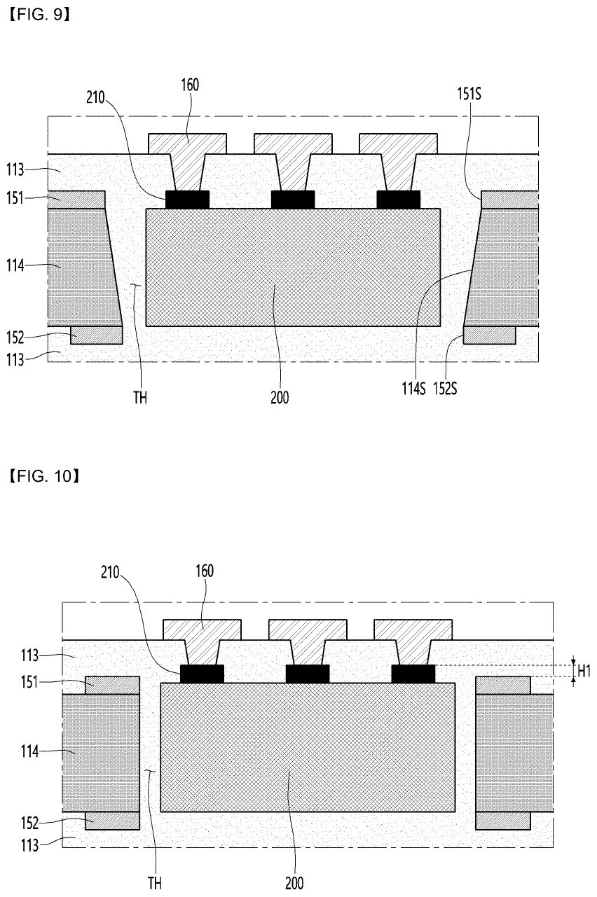

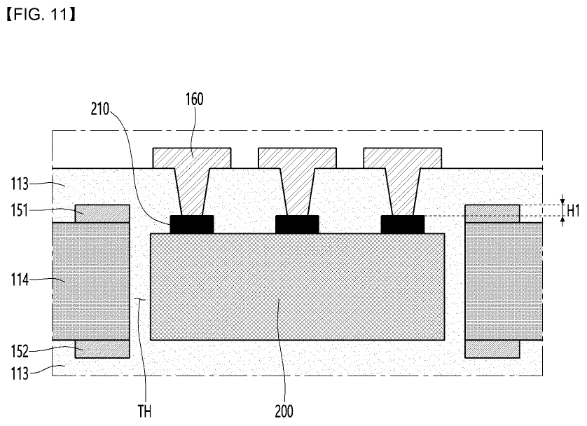

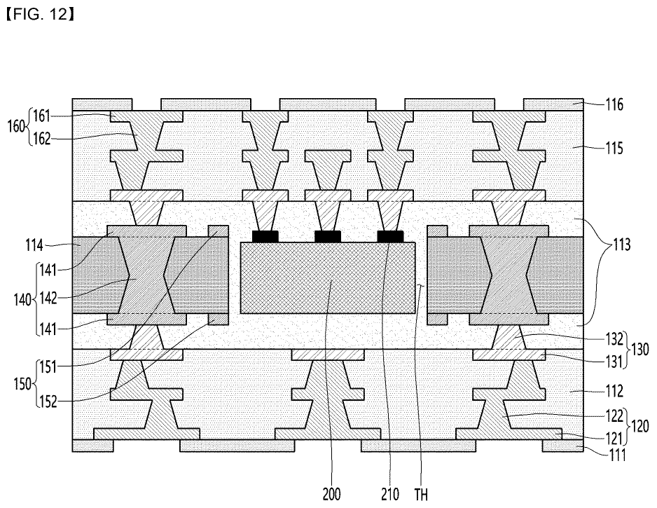

FIG. 2 is a cross-sectional view showing a circuit board according to a first embodiment, FIG. 3 is a cross-sectional view showing a first electrode part of FIG. 2, FIG. 4 is a cross-sectional view showing a second electrode part of FIG. 2, FIG. 5 is a cross-sectional view showing a third electrode part of FIG. 2, FIG. 6 is a plan view showing a dummy electrode of a third electrode part according to an embodiment, FIG. 7 is a cross-sectional view showing a dummy electrode and a through hole according to a first embodiment, FIG. 8 is a cross-sectional view showing a dummy electrode and a through hole according to a second embodiment, FIG. 9 is a cross-sectional view showing a dummy electrode and a through hole according to a third embodiment, FIG. 10 is a cross-sectional view showing positions of terminals of a dummy electrode and a connection member according to a first embodiment, FIG. 11 is a cross-sectional view showing positions of terminals of a dummy electrode and a connection member according to a second embodiment, and FIG. 12 is a cross-sectional view showing a circuit board according to a second embodiment.

Hereinafter, a semiconductor package according to an embodiment will be specifically described with reference to FIGS. 2 to 12.

Referring to FIG. 2, a semiconductor package may include a circuit board and a connection member 200 embedded in the circuit board.

In one embodiment, the connection member 200 may have a function of horizontally connecting a plurality of semiconductor devices disposed on the circuit board. For example, the connection member 200 may include high-density electrode patterns to connect the plurality of semiconductor devices. For this purpose, the connection member 200 in one embodiment may be an inorganic bridge. The inorganic bridge may include a silicon bridge. In addition, the connection member 200 in another embodiment may be an organic bridge. The organic bridge may include at least one organic insulating layer and electrode patterns disposed on the organic insulating layer.

In another embodiment, the connection member 200 may mean a semiconductor device. For example, in another embodiment, the connection member 200 may mean a semiconductor device embedded in the circuit board. The semiconductor device may include an active device and/or a passive device. The active device may be a semiconductor chip in the form of an integrated circuit (IC) in which hundreds to millions of devices are integrated in one semiconductor device. The semiconductor device may be an application processor (AP) device including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. In addition, the connection member 200 may be an integrated passive device (IPD). In addition, the connection member 200 may be a multilayer ceramic capacitor (MLCC, Multi-Layer Ceramic Condenser, Multi-Layer Ceramic Capacitor) or a Si-based capacitor.

The connection member 200 may be embedded in a circuit board and may be electrically connected to an electrode part included in the circuit board. For example, the connection member 200 may include a terminal, and the terminal may be electrically connected to an electrode part of the circuit board. The terminal may refer to an electrode pattern provided in an organic bridge and/or an inorganic bridge, and may refer to an electrode pattern provided in a semiconductor device.

The circuit board may provide a space for accommodating and embedding the connection member 200. The circuit board may provide a space in which at least one semiconductor device is mounted.

The circuit board may include an insulating layer and an electrode part. The insulating layer may be provided in a plurality of layers. In addition, the electrode part may be provided in each of the plurality of layers of the insulating layer. For example, the electrode part may be provided to penetrate at least a portion of a region of the plurality of layers of the insulating layer.

The insulating layer may include a first insulating layer 111.

The first insulating layer 111 may refer to an insulating layer positioned at a lowermost side among the insulating layers provided in the circuit board. The first insulating layer 111 may have a function of protecting the circuit board. Therefore, the first insulating layer 111 may be referred to as a resist layer or a protective layer.

The first insulating layer 111 may be a solder resist layer including an organic polymer material. For example, the first insulating layer 111 may include an epoxy acrylate series resin. In detail, the first insulating layer 111 may include a resin, a curing agent, a photo initiator, a pigment, a solvent, a filler, an additive, an acrylic series monomer, etc. However, the embodiment is not limited thereto, and the first insulating layer 111 may be provided with any one of a photo solder resist layer, a cover-lay, and a polymer material.

For example, when a semiconductor device and/or an external circuit board are bonded to an electrode part of an embodiment using a conductive adhesive such as solder, the solder and the first insulating layer 111 have poor wettability with each other, and thus, an electrical reliability problem that occurs when a plurality of adjacent solders come into contact with each other can be solved.

The first insulating layer 111 may not include a reinforcing member. The reinforcing member may also be referred to as a reinforcing fiber or a glass fiber.

The reinforcing member may be distinguished from a filler. For example, the reinforcing member may mean a glass fiber material extending in a horizontal direction within the insulating layer, and may have a different meaning from an inorganic filler that is spaced apart from each other. That is, the reinforcing member may have a different length or width from the filler in a horizontal direction. For example, the glass fiber may be extended to have a width greater than a width of the insulating layer. Here, the meaning of having a width greater than a width of the insulating layer may mean that the glass fiber may be disposed in a shape that is bent in a horizontal direction. The filler is distinguished from the reinforcing member, and for example, may refer to an inorganic filler.

The first insulating layer 111 may have a thickness in a vertical direction in a range of 6 μm to 20 μm. Preferably, the first insulating layer 111 may have a thickness in the vertical direction of 8 μm to 18 μm. The first insulating layer 111 may have a thickness in the vertical direction of 10 μm to 16 μm. The thickness of the first insulating layer 111 in the vertical direction may refer to a vertical distance from a lower surface of an electrode part most adjacent to the first insulating layer 111 to a lower surface of the first insulating layer 111. For example, the thickness of the first insulating layer 111 in the vertical direction may refer to a vertical distance from a lower surface of a first electrode part 120 in contact with the first insulating layer 111 to a lower surface of the first insulating layer 111.

If the thickness of the first insulating layer 111 in the vertical direction exceeds 20 μm, it may be difficult to thin the semiconductor package due to an increase in a thickness of the semiconductor package, or stress applied to the second insulating layer 112, the third insulating layer 113, and the fourth insulating layer 114 may increase. In addition, if the thickness of the first insulating layer 111 is smaller than 6 μm, it may be difficult to stably protect the circuit board and/or the electrode part, thereby reducing electrical reliability or physical reliability.

The circuit board may include a second insulating layer 112 disposed on the first insulating layer 111.

The second insulating layer 112 may include an insulating material different from that of the first insulating layer 111. The second insulating layer 112 may have rigidity. For example, the second insulating layer 112 may include a reinforcing member. The second insulating layer 112 may include reinforcing fibers and/or glass fibers. For example, the second insulating layer 112 may be a prepreg including a reinforcing member, but is not limited thereto.

The second insulating layer 112 may be provided on the first insulating layer 111 in at least one layer. When the second insulating layer 112 is provided in multiple layers, an interface between the multiple layers of the second insulating layer 112 may not be distinguished. In this case, the interface between the multiple layers of the second insulating layer 112 may be distinguished by the first electrode part 120 penetrating the second insulating layer 112. For example, the first electrode part 120 may include a pad part 121 and a through part 122. In addition, the pad part 121 and the through part 122 may have different widths in the horizontal direction and/or different slopes in the vertical direction. In addition, when the second insulating layer 112 is provided with a plurality of layers of a same insulating material, the interface of each layer can be distinguished based on a difference in width or slope of the pad part 121 and the through part 122 of the first electrode part 120.

A thickness of a single layer of the second insulating layer 112 in the vertical direction can satisfy a range of 15 μm to 35 μm. The thickness of a single layer of the second insulating layer 112 in the vertical direction can satisfy a range of 17 μm to 33 μm. The thickness of a single layer of the second insulating layer 112 in the vertical direction can satisfy a range of 20 μm to 30 μm. If the thickness of a single layer of the second insulating layer 112 in the vertical direction is smaller than 15 μμm, the reinforcing fibers provided in the second insulating layer 112 may be exposed from the second insulating layer 112, and an electrical reliability problem may occur due to the exposed reinforcing fibers coming into contact with the electrode part. If the thickness of a single layer of the second insulating layer 112 in the vertical direction is smaller than 15 μm, the rigidity of the semiconductor package is reduced, and as a result, a problem of the semiconductor package being greatly bent in a specific direction may occur. If the thickness of the single layer of the second insulating layer 112 in the vertical direction exceeds 35 μm, it may be difficult to thin the semiconductor package due to an increase in the thickness of the semiconductor package, or the stress applied to an adjacent insulating layer to the second insulating layer 112 may increase.

Preferably, the thickness of the single layer of the second insulating layer 112 in the vertical direction may be greater than the thickness of the first insulating layer 111 in the vertical direction. Through this, the second insulating layer 112 may prevent stress from being applied to a lower side of the first insulating layer 111, thereby improving the overall mechanical reliability of the semiconductor package.

Meanwhile, the second insulating layer 112 in FIG. 2 is illustrated as being provided in two layers, but is not limited thereto. The second insulating layer 112 may be provided in one layer, or may be provided in three or more layers.

The circuit board may include a third insulating layer 113 disposed on the second insulating layer 112. The third insulating layer 113 may include an insulating material different from an insulating material of the first insulating layer 111 and an insulating material of the second insulating layer 112.

The third insulating layer 113 may not include a reinforcing member. For example, the third insulating layer 113 may not include glass fiber and/or reinforcing fiber. The third insulating layer 113 may include an organic material that does not include a reinforcing member that enables slimming of the circuit board, excellent processability, and enables miniaturization of the electrode part. For example, the third insulating layer 113 may use ABF (Ajinomoto Build-up Film), a product released by Ajinomoto Co., Ltd. However, the embodiment is not limited thereto, and the third insulating layer 113 may include RCC (Resin Coated Copper) or PID (Photo Imageable Dielectric resin) that does not include a reinforcing member.

The third insulating layer 113 may prevent the semiconductor package from being greatly bent in a specific direction. For example, Young's Modulus of the third insulating layer 113 may be smaller than Young's Modulus of the second insulating layer 112, thereby preventing the semiconductor package from being bent. The Young's Modulus of the second insulating layer 112 may be 32 GPa/R.T, and the Young's Modulus of the third insulating layer 113 may be 5.0 GPa/R.T.

The third insulating layer 113 may be provided in multiple layers. For example, the third insulating layer 113 may be provided with multiple layers with the fourth insulating layer 114 interposed therebetween. At this time, the fourth insulating layer 114 is provided between the multiple layers of the third insulating layer 113, and accordingly, interfaces of the multiple layers of the third insulating layer 113 may be distinguished by the fourth insulating layer 114.

The third insulating layer 113 may include a first region disposed under the fourth insulating layer 114, a second region disposed on the fourth insulating layer 114, and a third region disposed in the through hole TH of the fourth insulating layer 114.

A thickness of each of the first region and the second region of the third insulating layer 113 in the vertical direction may be smaller than the thickness of a single layer of the second insulating layer 112 in the vertical direction and larger than the thickness of the first insulating layer 111 in the vertical direction. For example, the thickness in the vertical direction from the upper surface of the third insulating layer 113 to the upper surface of the fourth insulating layer 114 may be smaller than a thickness of a single layer of the second insulating layer 112 in the vertical direction. For example, the thickness in the vertical direction from the lower surface of the third insulating layer 113 to the lower surface of the fourth insulating layer 114 may be smaller than the thickness of a single layer of the second insulating layer 112 in the vertical direction. That is, the embodiment can control the thickness of the third insulating layer 113 within the range described below, thereby achieving optimal reliability of the semiconductor package.

For example, the thickness of the third insulating layer 113 in the vertical direction may satisfy a range of 10 μm to 30 μm. Preferably, the thickness of the third insulating layer 113 in the vertical direction may satisfy a range of 12 μm to 28 μm. More preferably, the thickness of the third insulating layer 113 in the vertical direction can satisfy a range of 15 μm to 25 μm.

If the thickness of the third insulating layer 113 in the vertical direction is smaller than 10 μm, a bending prevention effect of the semiconductor package exhibited by the third insulating layer 113 may be insufficient. For example, the third insulating layer 113 is provided between the fourth insulating layer 114 and the second insulating layer 112, and can have a function of absorbing impact applied to the semiconductor package while preventing the semiconductor package from being bent significantly in a specific direction. In addition, the third insulating layer 113 is provided while covering the connection member 200, and thereby can prevent impact from being applied to the connection member 200. At this time, if the thickness of the third insulating layer 113 in the vertical direction is smaller than 10μm, the impact absorption effect may be insufficient, and thus, the semiconductor package may be significantly bent in a specific direction, resulting in a problem of deterioration of operating characteristics, or a problem of cracks occurring in the connection member 200. In addition, if the thickness of the third insulating layer 113 in the vertical direction exceeds 30 μm, it may be difficult to thin the semiconductor package due to an increase in the thickness of the semiconductor package, or the stress applied to an adjacent insulating layer to the third insulating layer 113 may increase.

The circuit board may include a fourth insulating layer 114 embedded in the third insulating layer 113. For example, the third insulating layer 113 may be provided at upper and lower portions of the fourth insulating layer 114, and through this, the fourth insulating layer 114 may have a structure embedded in the third insulating layer 113.

The fourth insulating layer 114 may include an different insulating material from the first insulating layer 111, the second insulating layer 112, and the third insulating layer 113. In this case, the meaning of including different insulating materials may mean that a type of insulating material provided therein is different or a width and/or thickness of the insulating material are different.

The fourth insulating layer 114 may include a reinforcing member. For example, the fourth insulating layer 114 may include reinforcing fibers or glass fibers. At this time, the reinforcing member of the fourth insulating layer 114 may be a same type of reinforcing fibers or glass fibers as the reinforcing member of the second insulating layer 112.

However, a number of layers of the reinforcing member provided in the fourth insulating layer 114 and/or a thickness of the reinforcing member provided in the fourth insulating layer 114 may be different from a number of layers of the reinforcing member provided in the second insulating layer 112 and/or a thickness of the reinforcing member in the second insulating layer 112.

Preferably, the number of layers of the reinforcing member provided in the fourth insulating layer 114 may be greater than the number of layers of the reinforcing member provided in the second insulating layer 112. For example, the reinforcing member provided in the second insulating layer 112 may have a structure laminated in one or two layers. In addition, the reinforcing member provided in the fourth insulating layer 114 may have a structure laminated in 3 to 5 layers. In addition, a thickness in the vertical direction of the reinforcing member provided in the fourth insulating layer 114 may be greater than a thickness in the vertical direction of the reinforcing member provided in the second insulating layer 112. This means that the fourth insulating layer 114 is an insulating layer positioned at a center of a laminated structure of multiple insulating layers of the semiconductor package, and thus may serve as a core of the semiconductor package. In addition, the fourth insulating layer 114 must have a rigidity of a certain level or higher so that the overall rigidity of the semiconductor package can increase. Accordingly, in a manufacturing process of the semiconductor package, a process of laminating the insulating layer and a process of forming the electrode part can be stably performed at the upper and lower portions of the fourth insulating layer 114, respectively.

A thickness of the fourth insulating layer 114 may be larger than the thickness in the vertical direction of each single layer of the first insulating layer 111, the second insulating layer 112, and the third insulating layer 113.

For example, the thickness in the vertical direction of the fourth insulating layer 114 may satisfy a range of 50 μm to 110 μm. Preferably, the thickness of the fourth insulating layer 114 in the vertical direction may satisfy a range of 60 μm to 100 μm. More preferably, the thickness of the fourth insulating layer 114 in the vertical direction may satisfy a range of 70 μm to 90 μm. If the thickness of the fourth insulating layer 114 in the vertical direction is smaller than 50 μm, the fourth insulating layer 114 may not sufficiently perform a role of a core, and thus, the rigidity of the semiconductor package may be reduced, which may cause problems in a manufacturing process. For example, if the fourth insulating layer 114 does not function as a sufficient core, warpage of the semiconductor package may occur, and a problem may occur in which the electrode part is not formed in a correct position at the upper and lower portions of the fourth insulating layer 114. In addition, if the thickness of the fourth insulating layer 114 in the vertical direction exceeds 110 μm, it may be difficult to thin the semiconductor package due to an increase in the thickness of the semiconductor package.

Meanwhile, the fourth insulating layer 114 may include a through hole TH. The through hole TH may be referred to as a receiving portion in which the connection member 200 is received. A width of the through hole TH in the horizontal direction may be larger than a width of the connection member 200 in the horizontal direction. For example, an inner wall of the through hole TH of the fourth insulating layer 114 may be spaced apart from a side surface of the connection member 200 by a certain distance. Through this, the fourth insulating layer 114 may not be in contact with the connection member 200. The connection member 200 may be disposed in the through hole TH of the fourth insulating layer 114, and the third insulating layer 113 may be provided surrounding the connection member.

The circuit board may include a fifth insulating layer 115 disposed on the third insulating layer 113. The fifth insulating layer 115 may include a same insulating material as the second insulating layer 112. For example, the second insulating layer 112 and the fifth insulating layer 115 may be layers including a same insulating material, and the second insulating layer 112 and the fifth insulating layer 115 may be provided on the upper and lower portions thereof, respectively, with the third insulating layer 113 interposed therebetween. The characteristics of the fifth insulating layer 115 may correspond to the characteristics of the second insulating layer 112, and thus, a detailed description thereof will be omitted.

The circuit board may include a sixth insulating layer 116 disposed on the fifth insulating layer 115. The sixth insulating layer 116 may include a same insulating material as the first insulating layer 111. The characteristics of the sixth insulating layer 116 may correspond to the characteristics of the first insulating layer 111, and thus, a detailed description thereof will be omitted.

As described above, the insulating layer of the circuit board of the embodiment may be provided with a plurality of layers including a plurality of different insulating materials. That is, a fourth insulating layer 114 may be provided at a center of the circuit board, and a third insulating layer 113, a second insulating layer 112, and a first insulating layer 111 may be sequentially disposed under the fourth insulating layer 114, and a third insulating layer 113, a fifth insulating layer 115, and a sixth insulating layer 116 may be sequentially disposed on the fourth insulating layer 114. That is, the circuit board may be provided with a same insulating material symmetrically on the upper and lower portions thereof based on the fourth insulating layer 114. Based on this, the embodiment can prevent the circuit board from being bent by the laminated structure of the insulating layers having the upper and lower symmetrical structure.

Meanwhile, the circuit board includes an electrode part. The electrode part may be provided while penetrating at least some region of each of the second insulating layer 112, the third insulating layer 113, the fourth insulating layer 114, and the fifth insulating layer 115.

For example, the electrode part may include a first electrode part 120 penetrating at least some region of the second insulating layer 112, a second electrode part 130 penetrating at least some region of the third insulating layer 113, a third electrode part 140 penetrating at least some region of the fourth insulating layer 114, and a fourth electrode part 160 penetrating at least some region of the fifth insulating layer 115.

Each of the first electrode part 120, the second electrode part 130, the third electrode part 140, and the fourth electrode part 160 may include a pad part and a through part. The pad part may mean an electrode that transmits a signal in a horizontal direction in each insulating layer or is connected to the through part. The through part may penetrate at least some region of each insulating layer. Accordingly, the through part connect a plurality of pad parts disposed on different layers in a vertical direction. The through part may be referred to as a via electrode.

Specifically, referring to FIG. 3, the first electrode part 120 may include a first pad part 121 and a first through part 122.

The first pad part 121 of the first electrode part 120 may be provided at a lower surface of the second insulating layer 112. At least a portion of the lower surface of the first pad part 121 of the first electrode part 120 may be covered with the first insulating layer 111. In addition, the first insulating layer 111 may have at least one opening, and at least a portion of the first pad part 121 of the first insulating layer 111 may vertically overlap with the opening.

The first electrode part 120 may include a first through part 122 that penetrates at least some region of the second insulating layer 112 and is connected to the first pad part 121.

The first through part 122 of the first electrode part 120 may have a slope. For example, the first through part 122 of the first electrode part 120 may have a slope in which the width gradually decreases from a lower surface of the second insulating layer 112 toward an upper surface of the second insulating layer 112. For example, an inner angle of a side surface of the first through part 122 with respect to a lower surface of the first through part 122 may be an acute angle. A vertical cross-sectional shape of the first through part 122 of the first electrode part 120 may be a trapezoidal shape. An upper surface of the first through part 122 of the first electrode part 120 may have a smaller horizontal width than a lower surface of the first through part 122.

An outer wall 112S of the first through part 122 of the first electrode part 120 may include an uneven portion. Preferably, the outer wall 112S of the first through part 122 of the first electrode part 120 may be in contact with the second insulating layer 112. The second insulating layer 112 may include a resin layer 112a and reinforcing fibers 112b.

The outer wall 112S of the first through part 122 may include a portion in contact with the resin layer 112a and a portion in contact with the reinforcing fibers 112b. In addition, the portion in contact with the reinforcing fibers 112b of the first through part 122 may embed at least a portion of the reinforcing fibers 112b.

Accordingly, the outer wall 112S of the first through part 122 may include a concave portion 122CP in which the reinforcing fiber 112b of the second insulating layer 112 is disposed while horizontally overlapping with the reinforcing fiber 112b. The concave portion 122CP provided at the outer wall 112S of the first through part 122 may mean a portion in which the reinforcing fiber 112b of the second insulating layer 112 is disposed.

A vertical length of the concave portion 122CP provided at the outer wall 112S of the first through part 122 in the vertical direction may correspond to the thickness of the reinforcing fiber 112b provided in the second insulating layer 112. In addition, a plurality of concave portions may be provided at the outer wall 112S of the first through part 122 to spaced apart in the vertical direction. The number of the plurality of concave portions 122CP may correspond to the number of layers of reinforcing fibers 112b provided in the second insulating layer 112. For example, one or two layers of reinforcing fibers 112b may be provided in the second insulating layer 112, and one or two concave portions 122CP may be provided at the outer wall 112S of the first through part 122 of the first electrode part 120. Meanwhile, a slope of the outer wall 112S of the first through part 122 may vary in a portion corresponding to the concave portion 122CP. However, although not shown in the drawing, the second insulating layer 112 may be provided with a filler in addition to the reinforcing fiber 112b. Accordingly, the outer wall 112S of the first through part 122 of the first electrode part 120 may further include a concave portion and/or a convex portion corresponding to the filler in addition to the concave portion 122CP corresponding to the reinforcing fiber 112b.

Meanwhile, referring to FIG. 4, the second electrode part 130 may include a second pad part 131 and a second through part 132.

The second pad part 131 of the second electrode part 130 may be provided at a lower surface of the third insulating layer 113. At least a portion of the lower surface of the second pad part 131 of the second electrode part 130 may be covered with the second insulating layer 112.

The second electrode part 130 may include a second through part 123 that penetrates at least some region of the third insulating layer 113 and is connected to the second pad part 122.

The second through part 132 of the second electrode part 130 may have a slope. For example, the second through part 132 of the second electrode part 130 may have a slope whose width gradually decreases from the lower surface of the third insulating layer 113 toward the upper surface of the third insulating layer 113. For example, an inner angle of the side surface of the second through part 132 with respect to the lower surface of the second through part 132 may be an acute angle. A vertical cross-sectional shape of the second through part 132 of the second electrode part 130 may be a trapezoidal shape. An upper surface of the second through part 132 of the second electrode part 130 may have a horizontal width smaller than a lower surface of the second through part 132.

The second through part 132 of the second electrode part 130 may be inclined in a same direction as the first through part 122 of the first electrode part 120.

However, a slope of the second through part 132 of the second electrode part 130 may be different from a slope of the first through part 122 of the first electrode part 120.

Specifically, the second through part 132 of the second electrode part 130 may be provided within the third insulating layer 113 that does not have the reinforcing fiber. Accordingly, when forming a through hole penetrating the third insulating layer 113, there may be little difference between an upper surface width and a lower surface width of the through hole.

Accordingly, a slope of the second through part 132 of the second electrode part 130 may be greater than a slope of the first through part 122 of the first electrode part 120. For example, a slope of the side surface of the second through part 132 of the second electrode part 130 with respect to the lower surface of the second through part 132 of the second electrode part 130 may be greater than a slope of the side surface of the first insulating layer 111 with respect to the lower surface of the first through part 122 of the first electrode part 120. In addition, a width of the second through part 132 of the second electrode part 130 in the horizontal direction may be smaller than a width of the first through part 122 of the first electrode part 120 in the horizontal direction. At this time, the second electrode part 130 may include an electrode connected to the connection member 200 embedded in the fourth insulating layer 114. In addition, the connection member 200 may be provided with fine terminals. Therefore, the embodiment may provide an electrode part connected to the terminal of the connection member 200 in the third insulating layer 113. Through this, the embodiment may enable the miniaturization of the second electrode part 130 connected to the connection member 200 while accurately positioning the second electrode part 130 in a region corresponding to the terminal of the connection member 200. Furthermore, the embodiment may smoothly transmit a signal transmitted from the connection member 200 through the second electrode part 130, thereby minimizing signal transmission loss and improving electrical characteristics accordingly.

Meanwhile, the second through part 132 of the second electrode part 130 may not have a concave portion corresponding to the first through part 122 of the first electrode part 120. For example, the second through part 132 of the second electrode part 130 may not overlap with the reinforcing fibers in the horizontal direction. However, the third insulating layer 113 may be provided with a filler, and an outer surface of the second through part 132 may include a concave portion and/or a convex portion in contact with the filler.

Meanwhile, referring to FIG. 5, the fourth insulating layer 114 may be provided with a third electrode part 140. The third electrode part 140 may include a third pad part 141 and a third through part 142.

The third pad part 141 of the third electrode part 140 may be provided on the upper and lower surfaces of the fourth insulating layer 114, respectively. In addition, the third through part 142 of the third electrode part 140 may penetrate the fourth insulating layer 114 while being connected to the third pad part 141 of the third insulating layer 113.

The third through part 142 of the third electrode part 140 may include a plurality of slopes.

The third through part 142 of the third electrode part 140 may include a first slope 142S1 that is adjacent to an upper surface of the fourth insulating layer 114 and whose width gradually decreases toward the lower surface of the fourth insulating layer 114. In addition, the third through part 142 of the third electrode part 140 may include a second slope 142S2 that is adjacent to the lower surface of the fourth insulating layer 114 and whose width gradually decreases toward the upper surface of the fourth insulating layer 114. The first slope 142S1 and the second slope 142S2 may be different from each other. For example, the first slope 142S1 and the second slope 142S2 may be inclined in different directions.

The embodiment can allow the third through part 142 of the third electrode part 140 to include a plurality of slopes. Through this, the embodiment can allow the third through part 142 of the third electrode part 140 to easily penetrate the fourth insulating layer 114 having a relatively large thickness and relatively large reinforcing fibers. Through this, the embodiment can solve a problem that the third through part 142 of the third electrode part 140 does not penetrate the fourth insulating layer 114, and can improve electrical reliability accordingly.

Meanwhile, the fourth insulating layer 114 can include a resin layer 114a and reinforcing fibers 114b. In addition, the third through part 142 of the third electrode part 140 may include a concave portion 142CP horizontally overlapped with the reinforcing fiber 114b of the fourth insulating layer 114.

At this time, the concave portion 122CP provided in the first through part 122 of the first electrode part 120 may be different from the concave portion 142CP provided in the third through part 142 of the third electrode part 140.

For example, a vertical length in the vertical direction of the concave portion 142CP provided in the third through part 142 of the third electrode part 140 and/or the number of the concave portions 142CP may be different from the vertical length in the vertical direction of the concave portion 122CP provided in the first through part 122 of the first electrode part 120 and/or the number of the concave portions 122CP.

Specifically, the vertical length in the vertical direction of the concave portion 142CP provided in the third through part 142 of the third electrode part 140 may be greater than the vertical length in the vertical direction of the concave portion 122CP provided in the first through part 122 of the first electrode part 120. In addition, the number of concave portions 142CP provided in the third through part 142 of the third electrode part 140 may be greater than the number of concave portions 122CP provided in the first through part 122 of the first electrode part 120.

Meanwhile, the fourth electrode part 160 may include a fourth pad part 161 and a fourth through part 162. The fourth pad part 161 and the fourth through part 162 of the fourth electrode part 160 may have structures corresponding to the first pad part 121 and the second through part 122 of the first electrode part 120. For example, the fourth pad part 161 and the fourth through part 162 of the fourth electrode part 160 may have a symmetrical structure with the first pad part 121 and the second through part 122 of the first electrode part 120.

In addition, the circuit board may include a protruding electrode part 170. The protruding electrode part 170 may include a protruding part 171 protruding onto the sixth insulating layer 116 and a through part 172 penetrating at least some region of the sixth insulating layer 116.

The protruding electrode part 170 may be a post bump connected to the semiconductor device.

That is, as a width of the terminal of the semiconductor device coupled to the circuit board and a pitch of the terminals are miniaturized, when the semiconductor device is mounted using a conductive adhesive such as solder, diffusion of the conductive adhesive may occur, and this may cause a problem in which a plurality of conductive adhesives are connected to each other. Through this, the embodiment can perform thermal compression bonding to reduce a volume of the conductive adhesive. At this time, if the protruding electrode part 170 is not provided on the circuit board, it may be difficult to reduce a volume of the conductive adhesive. This may be because a height of the electrode on which the conductive adhesive is disposed is lower than the upper surface of the sixth insulating layer 116, and thus the volume of the conductive adhesive increases by a difference between a height of the electrode and a height of the insulating layer.

Therefore, the embodiment can have a protruding electrode part 170 having a protruding structure to secure alignment with the terminal of the semiconductor device and diffusion prevention power to prevent the intermetallic compound (IMC) formed between the conductive adhesive and the electrode part from diffusing into the circuit board.

Meanwhile, the circuit board may include a dummy electrode 150. The dummy electrode 150 may include a first dummy electrode 151 provided on the upper surface of the fourth insulating layer 114 and a second dummy electrode 152 provided on the lower surface of the fourth insulating layer 114.

Referring to FIG. 6, the dummy electrode 150 may be provided to surround a through hole TH provided in the fourth insulating layer 114. For example, the first dummy electrode 151 of the dummy electrode 150 may be provided to surround an upper region of the through hole TH. In addition, the second dummy electrode 152 of the dummy electrode 150 may be provided to surround a lower region of the through hole TH.

Each of the first dummy electrode 151 and the second dummy electrode 152 of the dummy electrode 150 may have a ring shape. Each of the first dummy electrode 151 and the second dummy electrode 152 of the dummy electrode 150 may have a closed loop shape. Each of the first dummy electrode 151 and the second dummy electrode 152 of the dummy electrode 150 may have a shape corresponding to a planar shape of the through hole TH.

The dummy electrode 150 may have a first width W1. The first width W1 of the dummy electrode 150 may satisfy a range of 80 μm to 120 μm. Preferably, the first width W1 of the dummy electrode 150 may satisfy a range of 85 μm to 115 μm. More preferably, the first width W1 of the dummy electrode 150 may satisfy a range of 90 μm to 110 μm. If the first width W1 of the dummy electrode 150 is less than 80 μm, damage to a portion of the fourth insulating layer 114 may occur during a process of forming the through hole TH. In addition, in order to prevent damage to a portion of the fourth insulating layer 114, a position of the laser must be adjusted during a process of forming the through hole TH, and accordingly, an inner wall of the through hole TH may have a slope that is significantly different from 90 degrees. In addition, if the first width W1 of the dummy electrode 150 exceeds 120 μm, a dummy region in the fourth insulating layer 114 increases, and thus, it may be difficult to thin the semiconductor package.

Meanwhile, a width of the through hole TH may be larger than the width of the connection member 200. Preferably, an area of the through hole TH may be larger than an area of the connection member 200.

For example, a horizontal distance W2 between a side wall of the through hole TH and a side surface of the connection member 200 may satisfy a range of 75 μm to 120 μm. Preferably, the horizontal distance W2 between the side wall of the through hole TH and the side surface of the connection member 200 may satisfy a range of 75 μm to 120 μm. More preferably, the horizontal distance W2 between the side wall of the through hole TH and the side surface of the connection member 200 may satisfy a range of 75 μm to 120 μm.

If the horizontal distance W2 between the sidewall of the through hole TH and the side surface of the connection member 200 is smaller than 75 μm, the connection member 200 may come into contact with the sidewall of the through hole TH due to a process error in a process of embedding the connection member 200, and thus the connection member 200 may be damaged. In addition, if the horizontal distance W2 between the sidewall of the through hole TH and the side surface of the connection member 200 exceeds 120 um, the dummy region increases by the horizontal distance, and thus, it may be difficult to thin the semiconductor package.

Meanwhile, referring to FIG. 7, the sidewall 114S of the through hole TH may be perpendicular to the upper or lower surface of the fourth insulating layer 114. This may be due to positions of the first dummy electrode 151 and the second dummy electrode 152 provided in the fourth insulating layer 114.

The first dummy electrode 151 may include a side surface 151S surrounding the through hole TH. In addition, the second dummy electrode 152 may include a side surface 152S surrounding the through hole TH.

In addition, the side surface 114S of the first dummy electrode 151 may be located on a same plane as the side wall 114S of the through hole TH. In addition, the side surface 152S of the second dummy electrode 152 may be located on a same plane as the side wall 114S of the through hole TH. In addition, the side surface 151S of the first dummy electrode 151 may be positioned on a same plane as the side surface 152S of the second dummy electrode 152.

In other words, the side surfaces of each of the first dummy electrode 151 and the second dummy electrode 152 may be positioned vertically on the same plane, and accordingly, the inner wall 114S of the through hole TH provided in the fourth insulating layer 114 may be positioned on the same plane as the side surfaces of each of the first dummy electrode 151 and the second dummy electrode 152. Through this, the embodiment may be able to have substantially the same upper and lower widths of the through hole TH. Therefore, the embodiment may minimize an increase in the dead region caused by a difference between the upper and lower widths of the through hole TH, and thus may thin the semiconductor package.

Meanwhile, the embodiment may allow the sidewall 114S of the through hole TH to have a certain slope depending on a shape or application design of the connection member 200.

For example, referring to FIG. 8, the side surface 151S of the first dummy electrode 151 may be disposed to be vertically misaligned with the side surface 152S of the second dummy electrode 152. The side surface 151S of the first dummy electrode 151 may be positioned closer to the connection member 200 than the side surface 152S of the second dummy electrode 152. Through this, the side wall 114S of the through hole TH may have a slope whose width gradually decreases from the lower surface to the upper surface of the fourth insulating layer 114.

For example, referring to FIG. 9, the side surface 151S of the first dummy electrode 151 may be disposed to be vertically misaligned with the side surface 152S of the second dummy electrode 152. The side surface 151S of the first dummy electrode 151 may be spaced further from the connection member 200 than the side surface 152S of the second dummy electrode 152. Through this, the side wall 114S of the through hole TH may have a slope whose width gradually increases from the lower surface of the fourth insulating layer 114 toward the upper surface.

Meanwhile, as illustrated in the previous drawing, the upper surface of the first dummy electrode 151 may be positioned on the same plane as the upper surface of the terminal 210 of the connection member 200. However, it is difficult to exactly match a thickness of the connection member 200 and a thickness of the fourth insulating layer 114, and it may be difficult to exactly match a thickness of the terminal 210 and a thickness of the first dummy electrode 151.

Therefore, in the embodiment, an upper surface of the terminal 210 of the connection member 200 and an upper surface of the first dummy electrode 151 may have a step.

Referring to FIG. 10, the upper surface of the terminal 210 of the connection member 200 may be positioned higher than the upper surface of the first dummy electrode 151 by a first height H1. At this time, the first height H1 may be smaller than a thickness of the first dummy electrode 151 in the vertical direction. Preferably, the first height H1 may be 8 μm or less. More preferably, the first height H1 may be 5 μm or less. In addition, referring to FIG. 11, the upper surface of the terminal 210 of the connection member 200 may be positioned lower than the upper surface of the first dummy electrode 151 by a first height H1. At this time, the first height H1 may be smaller than the thickness of the first dummy electrode 151 in the vertical direction. Preferably, the first height H1 may be 8 μm or less.

That is, if the step between the upper surface of the terminal 210 of the connection member 200 and the upper surface of the first dummy electrode 151 is greater than 8 μm, it may be difficult to ensure that the first electrodes connected to the terminal 210 of the connection member 200 and the second electrodes horizontally overlapping with the first electrodes in the third electrode part 140 have uniform heights, and thus the mechanical reliability and physical reliability of the semiconductor package may be deteriorated.

However, in the embodiment, if the upper surface of the terminal 210 of the connection member 200 is positioned lower than the upper surface of the first dummy electrode 151, a void may occur in a process of filling the through hole TH of the fourth insulating layer 114 with the third insulating layer 113. Accordingly, the upper surface of the terminal 210 of the connection member 200 is positioned higher than the upper surface of the first dummy electrode 151, thereby minimizing the occurrence of the void.

Meanwhile, referring to FIG. 12, the circuit board of the second embodiment may have a different structure of the electrode part compared to the circuit board of FIG. 2.

For example, the circuit board may include a first insulating layer 111, a second insulating layer 112, a third insulating layer 113, a fourth insulating layer 114, a fifth insulating layer 115, and a sixth insulating layer 116.

In addition, the circuit board may include a connection member 200 embedded in a through hole TH provided in the fourth insulating layer 114.

In addition, the circuit board may include a first electrode part 120 including a first pad part 121 and a first through part 122. In addition, the circuit board may include a second electrode part 130 including a second pad part 131 and a second through part 132. In addition, the circuit board may have a third electrode part 140 including a third pad part 141 and a third through part 142. In addition, the circuit board may have a fourth electrode part 160 including a fourth pad part 161 and a fourth through part 162. In addition, the circuit board may have a dummy electrode part 150 including a first dummy electrode 151 and a second dummy electrode 152.

At this time, among the electrode parts of the second embodiment, the electrode parts provided in the second insulating layer 112 and the fifth insulating layer 115 including a same insulating material may be different from the electrode parts of the first embodiment.

For example, the circuit board may have a first electrode part 120 and a fourth electrode part 160 provided at an outermost layer among the plurality of electrode parts. At this time, the first pad part 121 of the first electrode part 120 of the first embodiment may have a structure protruding below the lower surface of the second insulating layer 112. In addition, the fourth pad part 161 of the fourth electrode part 160 of the first embodiment may have a structure protruding above the upper surface of the fifth insulating layer 115.

Differently, the first pad part 121 of the first electrode part 120 of the second embodiment may have a structure embedded in the second insulating layer 112. In addition, the fourth pad part 161 of the fourth electrode part 160 of the second embodiment may have a structure embedded in the fifth insulating layer 115.

Here, a fact that the first pad part has an embedded structure may mean that at least a portion of the side surface of the first pad part 121 is covered with the second insulating layer 112. In addition, a fact that the first pad part has an embedded structure may mean that the upper surface of the first pad part 121 is positioned higher than the lower surface of the second insulating layer 112.

In addition, a fact that the fourth pad part has an embedded structure may mean that at least a portion of the side surface of the fourth pad part 141 is covered by the fifth insulating layer 115. In addition, a fact that the fourth pad part has an embedded structure may mean that the lower surface of the fourth pad part 151 is positioned lower than the upper surface of the fifth insulating layer 115.

Through this, the embodiment can prevent the pad part provided at the outermost layer of the circuit board from collapsing or peeling off by having a structure in which the pad part is embedded in the insulating layer, and thereby can further refine the pad part. In addition, the embodiment can reduce a thickness of the circuit board by an embedded depth of the pad part in the insulating layer, thereby enabling the thinning of the semiconductor package.

In addition, the through parts provided in each of the electrode parts of the embodiment can be provided misaligned rather than aligned on a same vertical line. Through this, the embodiment can improve the degree of design freedom in forming the through part.

Meanwhile, in FIG. 12, the lower surface of the first pad part 121 is illustrated as being located on a same plane as the lower surface of the second insulating layer 112, but is not limited thereto.

For example, the lower surface of the first pad part 121 in another embodiment can be located lower than the lower surface of the second insulating layer 112. In addition, the upper surface of the fourth pad part 161 in another embodiment can be located higher than the upper surface of the fifth insulating layer 115. In this case, a conductive adhesive material may be disposed on the lower surface of the first pad part 121 and/or the upper surface of the fourth pad part 161, and at this time, the first pad part 121 and the fourth pad part 161 may function as the protruding electrodes in the first embodiment. Through this, the alignment with the conductive adhesive material may be improved while preventing diffusion of the conductive adhesive material.

In addition, in another embodiment, the lower surface of the first pad part 121 may be positioned higher than the lower surface of the second insulating layer 112. In addition, in another embodiment, the upper surface of the fourth pad part 161 may be positioned lower than the upper surface of the fifth insulating layer 115. In this embodiment, a volume of the conductive adhesive material disposed on the first pad part 121 and/or the fourth pad part 161 can be increased compared to the previous embodiment, while preventing diffusion of the conductive adhesive material, thereby further improving the bonding strength with the semiconductor device.

The semiconductor package of the embodiment includes a first insulating layer, a second insulating layer disposed on the first insulating layer, a third insulating layer disposed on the second insulating layer, a fourth insulating layer embedded in the third insulating layer, and a fifth insulating layer disposed on the third insulating layer, wherein the first insulating layer, the second insulating layer, the third insulating layer, and the fourth insulating layer are formed of different materials, the second insulating layer and the fifth insulating layer are formed of a same material, and a thickness in a vertical direction between an upper surface of the fourth insulating layer and an upper surface of the third insulating layer may be smaller than a thickness of the second insulating layer in a vertical direction. Through this, the embodiment can reduce a thickness of the semiconductor package while preventing the semiconductor package from being bent in a specific direction by using the third insulating layer.

Specifically, the third insulating layer may have a relatively low Young's modulus, thereby suppressing an occurrence of warpage acting on the semiconductor package, and further preventing the semiconductor package from being greatly bent in a specific direction while absorbing an impact applied to the semiconductor package. Through this, the embodiment may solve a problem of deterioration of operating characteristics due to the semiconductor package being greatly bent in a specific direction, and further may solve a problem of damage to the connection member disposed in the third insulating layer due to the impact. In addition, the embodiment may arrange an electrode part connected to the connection member using the third insulating layer, thereby improving an alignment between the electrode part and the connection member.

In addition, the fourth insulating layer may include a through hole, and the connection member may be disposed in the through hole. In addition, a first dummy electrode may be provided at an upper surface of the fourth insulating layer, and a second dummy electrode may be provided at a lower surface of the fourth insulating layer. At least one side surface of the first dummy electrode and the second dummy electrode may be located on a same plane as a sidewall of the through hole. The first and second dummy electrodes may be electrodes used to form the through hole by a laser process. In addition, the embodiment may use the first and second dummy electrodes to make upper and lower widths of the through hole substantially the same, thereby reducing an area of a dead region that increases by a difference between the upper and lower widths. Accordingly, the embodiment can reduce a thickness of the semiconductor package.

In addition, the embodiment may change a shape of the through hole by making the first dummy electrode and the second dummy electrode misaligned along the vertical direction. Through this, the embodiment may freely change a shape of the through hole according to a shape of the connection member, thereby improving a degree of design freedom.

In addition, the embodiment may have a step between an upper surface of a terminal of the connection member and an upper surface of the first dummy electrode, and manage the step to be maintained below a certain level. Through this, the embodiment may increase a connection alignment between the electrode part and the terminal, and further minimize voids that occur in a process of filling the through hole with an insulating material.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1-10. (canceled)

11. A circuit board comprising:
a build-up insulating part including a plurality of insulating layers stacked along a vertical direction;
a build-up electrode part including a plurality of wiring electrodes disposed on one surface of each of the plurality of insulating layers, and a plurality of via electrodes electrically connecting the plurality of wiring electrodes; and
a semiconductor device embedded in the build-up insulating part and including a terminal electrically connected to the build-up electrode part,
wherein an upper surface of a first wiring electrode disposed closest to the terminal among the plurality of wiring electrodes and an upper surface of the terminal are misaligned along a horizontal direction.

12. The circuit board of claim 11, wherein the build-up insulating part includes:
a first insulating layer;
a second insulating layer disposed on the first insulating layer;
a third insulating layer disposed on the second insulating layer;
a fourth insulating layer embedded in the third insulating layer and having a through hole in which the semiconductor device is disposed; and
a fifth insulating layer disposed on the third insulating layer,
wherein the terminal is disposed closer to an upper surface of the fourth insulating layer than to a lower surface of the fourth insulating layer,
wherein the first wiring electrode is disposed on the upper surface of the fourth insulating layer, and
wherein the upper surface of the first wiring electrode and the upper surface of the terminal are misaligned along the horizontal direction.

13. The circuit board of claim 12, wherein the first insulating layer, the second insulating layer, the third insulating layer, and the fourth insulating layer are provided with different materials,
wherein the second insulating layer and the fifth insulating layer are provided with a same material,
wherein a thickness in a vertical direction between an upper surface of the fourth insulating layer and an upper surface of the third insulating layer is smaller than a thickness of the second insulating layer in the vertical direction, and
wherein a thickness in the vertical direction between a lower surface of the fourth insulating layer and a lower surface of the third insulating layer is smaller than the thickness of the second insulating layer in the vertical direction.

14. The circuit board of claim 13, wherein the second insulating layer includes a first resin layer and a first reinforcing member provided within the first resin layer,
wherein the fourth insulating layer includes a second resin layer and a second reinforcing member provided within the second resin layer, and
wherein a number of layers or thickness of the first reinforcing member is different from a number of layers or thickness of the second reinforcing member.

15. The circuit board of claim 14, wherein the first and second reinforcing members includes glass fibers or reinforcing fibers that are distinct from the filler.

16. The circuit board of claim 15, wherein the number of layers of the first reinforcing member is smaller than the number of layers of the second reinforcing member.

17. The circuit board of claim 15, wherein a thickness of a single layer of the first reinforcing member is smaller than a thickness of a single layer of the second reinforcing member.

18. The circuit board of claim 15, wherein the third insulating layer does not have a reinforcing member.

19. The circuit board of claim 18, wherein the plurality of the via electrodes include:
a first via electrode penetrating at least some region of the second insulating layer;
a second via electrode penetrating at least some region of the third insulating layer; and
a third electrode part penetrating upper and lower surfaces the fourth insulating layer,
wherein a thickness of the first via electrode in the vertical direction is greater than a thickness of the second via electrode in the vertical direction and smaller than a thickness of the third via electrode in the vertical direction,
wherein the thickness of the second via electrode in the vertical direction is smaller than the thickness of each of the first and third via electrodes in the vertical direction, and
wherein the thickness of the third via electrode in the vertical direction is greater than the thickness of each of the first and second via electrodes in the vertical direction.

20. The circuit board of claim 19, wherein a plurality of concave portions are provided at a side surface of each of the first via electrode and the third via electrode, and
wherein a number of concave portions provided in the first via electrode or a thickness of each of the plurality of concave portions provided in the first via electrode is different from a number of concave portions provided in the third via electrode or a thickness of each of the plurality of concave portions provided in the first via electrode.

21. The circuit board of claim 20, wherein the number of concave portions provided in the first via electrode or the thickness of each of the plurality of concave portions provided in the first via electrode is smaller than the number of concave portions provided in the third via electrode or the thickness of each of the plurality of concave portions provided in the first via electrode.

22. The circuit board of claim 21, wherein a side surface of the second via electrode does not have a concave portion.

23. The circuit board of claim 12, wherein the first wiring electrode overlaps the connection member in the horizontal direction, and
wherein the upper surface of the first wiring electrode is positioned higher than the upper surface of the terminal of the connection member based on a lower surface of the fourth insulating layer.

24. The circuit board of claim 12, wherein the first wiring electrode overlaps the connection member in the horizontal direction, and
wherein the upper surface of the first wiring electrode is positioned lower than the upper surface of the terminal of the connection member based on a lower surface of the fourth insulating layer.

25. The circuit board of claim 12, wherein the first wiring electrode includes a first dummy electrode disposed on an upper surface of the fourth insulating layer and disposed along a circumferential direction of an upper end of the through hole, and
wherein the build-up electrode part includes a second dummy electrode disposed on a lower surface of the fourth insulating layer and disposed along the circumferential direction of a lower end of the through hole.

26. The circuit board of claim 25, wherein at least one of an inner surface of the first dummy electrode and an inner surface of the second dummy electrode is located on a same plane as a side wall of the through hole of the fourth insulating layer.

27. The circuit board of claim 26, wherein the inner surface of the first dummy electrode, the inner surface of the second dummy electrode, and the sidewall of the through hole of the fourth insulating layer are located on the same plane.

28. The circuit board of claim 26, wherein the inner surface of the first dummy electrode and the inner surface of the second dummy electrode are misaligned with each other along the vertical direction.

29. The circuit board of claim 28, wherein an upper width and a lower width of the through hole are different from each other.

30. The circuit board of claim 12, wherein a vertical distance between the upper surface of the terminal of the connection member and the upper surface of the first wiring electrode is 8μm or less.
